(19) United States
(12) Patent Application Publication
(10) Pub. No.: US 2026/0198273 A1
(43) Pub. Date: Jul. 9, 2026

(54) BOTTOM-UP GAP FILL USING A LINER

(71) Applicant: Lam Research Corporation, Fremont, CA (US)

(72) Inventors: Daniel Christopher MESSINA, Beaverton, OR (US); Douglas Walter AGNEW, Portland, OR (US); Jennifer Leigh PETRAGLIA, Portland, OR (US)

(21) Appl. No.: 19/132,776

(22) PCT Filed: Dec. 13, 2023
(86) PCT No.: PCT/US2023/083884

§ 371 Date: May 23, 2025

Related U.S. Application Data
(60) Provisional application No. 63/476,149, filed on Dec. 19, 2022.

(51) Int. Cl. H10W 10/00; C23C 16/04; C23C 16/34; C23C 16/40; C23C 16/455; H10P 14/60; H10P 14/692; H10P 14/694

(52) U.S. Cl. CPC H10W 10/014; C23C 16/045; C23C 16/345; C23C 16/401; C23C 16/45527; C23C 16/45536; H10P 14/6339; H10P 14/6506; H10P 14/69215; H10P 14/69433

(57) ABSTRACT

Examples are disclosed that relate to performing a partial gap fill process in a bottom-up manner using atomic layer deposition (ALD). One example provides a method for partially filling a gap in a substrate. The method comprises depositing a sub-conformal layer of silicon nitride in a first portion of the gap and not in a second portion of the gap. The first portion extends from a top of the gap to a selected depth within the gap. The second portion extends from the selected depth to a bottom of the gap. The method further comprises performing a plurality of ALD cycles to deposit a silicon-containing oxide in the second portion of the gap. An ALD cycle comprises exposing the substrate to a silicon-containing precursor and reacting the silicon-containing precursor with an oxidant to deposit the silicon-containing oxide on a surface in the second portion of the gap.

### BACKGROUND

Electronic device fabrication processes involve many steps of material deposition, patterning, and removal to form integrated circuits on substrates. Various methods can be used to deposit films of materials onto a substrate. As an example, atomic layer deposition (ALD) deposits a film in a layer by layer manner using cycles. In an ALD cycle, a film precursor gas is adsorbed onto a surface of a substrate disposed in a process chamber. Excess film precursor is purged from the chamber. Then, the adsorbed film precursor is chemically converted into a film on the substrate. A highly conformal film of target thickness can be grown in such a manner.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to performing a partial gap fill process in a bottom-up manner using atomic layer deposition (ALD). One example provides a method for partially filling a gap in a substrate disposed in a processing chamber. The method comprises depositing a sub-conformal layer of silicon nitride in a first portion of the gap and not in a second portion of the gap. The first portion extends from a top of the gap to a selected depth within the gap. The second portion extends from the selected depth to a bottom of the gap. The method further comprises performing a plurality of ALD cycles to deposit a silicon-containing oxide in the second portion of the gap. An ALD cycle of the one or more ALD cycles comprises exposing the substrate to a silicon-containing precursor to adsorb the silicon-containing precursor to a surface in the second portion of the gap. The ALD cycle of the one or more ALD cycles further comprises reacting the silicon-containing precursor with an oxidant to deposit the silicon-containing oxide on the surface in the second portion of the gap.

In some such examples, an ALD cycle of the one or more ALD cycles comprises exposing the substrate to an inhibitor under conditions configured to deposit the inhibitor into the gap such that a concentration of the inhibitor deposited at a first depth within the gap is greater than a concentration of the inhibitor deposited at a second depth within the gap, the second depth being within the second portion of the gap and the second depth being farther from the top of the gap than the first depth.

In some such examples, exposing the substrate to the inhibitor additionally or alternatively comprises exposing the substrate to a fluorine-containing inhibitor.

In some such examples, the fluorine-containing inhibitor additionally or alternatively comprises one or more of molecular fluorine, hydrogen fluoride, boron trifluoride, phosphorus trifluoride, nitrogen trifluoride, a chlorofluorocarbon, a fluorocarbon, a hydrofluorocarbon, a chalcogen fluoride, a chalcogen chloride, or an interhalogen.

In some such examples, the method additionally or alternatively comprises removing the sub-conformal layer of silicon nitride from the first portion of the gap after depositing the silicon-containing oxide.

In some such examples, depositing the sub-conformal layer of silicon nitride additionally or alternatively comprises exposing the substrate to one or more of a halosilane precursor or an aminosilane precursor, purging the processing chamber, and forming a plasma comprising reactive nitrogen species.

In some such examples, forming the plasma additionally or alternatively comprises forming the plasma for a duration within a range of 0.05 to 60 seconds.

In some such examples, the substrate additionally or alternatively comprises a stack of layers of silicon alternating with silicon germanium, a stack of layers of polysilicon alternating with silicon oxide, or a stack of layers of silicon nitride alternating with silicon oxide.

In some such examples, the gap additionally or alternatively comprises a trench for forming a trench isolation region in a logic device.

Another example provides a method for processing a substrate comprising a gap. The method comprises depositing a liner in a first portion of the gap, the first portion extending from a top of the gap to a selected depth within the gap, and not depositing the liner in a second portion of the gap that extends from the selected depth to a bottom of the gap. The method further comprises performing a plurality of ALD cycles to deposit a silicon-containing oxide in the second portion of the gap. An ALD cycle of the plurality of ALD cycles comprising exposing the substrate to an inhibitor under conditions configured to deposit the inhibitor into the gap such that a concentration of the inhibitor deposited at a first depth is greater than a concentration of the inhibitor deposited at a second depth within the gap. The second depth is within the second portion of the gap and the second depth is farther from the top of the gap than the first depth.

In some such examples, the method further comprises removing the liner from the first portion of the gap.

In some such examples, depositing the liner additionally or alternatively comprises depositing a silicon nitride liner.

In some such examples, depositing the liner additionally or alternatively comprises forming a plasma.

In some such examples, the ALD cycle of the plurality of ALD cycles additionally or alternatively comprises exposing the substrate to a silicon-containing precursor to absorb the silicon-containing precursor onto the substrate and then oxidizing the silicon-containing precursor.

In some such examples, the method additionally or alternatively comprises performing an ALD cycle of the plurality of ALD cycles that omits exposing the substrate to the inhibitor.

In some such examples, the inhibitor additionally or alternatively comprises one or more of molecular fluorine, hydrogen fluoride, boron trifluoride, phosphorus trifluoride, nitrogen trifluoride, a chlorofluorocarbon, a fluorocarbon, a hydrofluorocarbon a chalcogen fluoride, a chalcogen chloride, or an interhalogen.

Another example provides a structure formed on a substrate in an integrated circuit manufacturing process. The structure comprises a gap. The structure further comprises a silicon nitride film disposed within a first portion of the gap. The first portion extends from an opening of the gap to a selected depth within the gap. The structure further comprises an oxide film within the gap. The oxide film at least partially fills a second portion of the gap. The second portion of the gap extends from the selected depth to a bottom of the gap.

In some such examples, the silicon nitride film comprises a halogenated surface.

In some such examples, the structure additionally or alternatively is part of a three-dimensional memory structure.

In some such examples, the silicon nitride film additionally or alternatively comprises a thickness within a range of 3-100 Å.

### BRIEF DESCRIPTION OF THE DRAWINGS

FIGS. 1A-IF schematically show structures formed in an example process for performing bottom-up gap fill utilizing a liner.

FIG. 2 schematically shows a structure formed by depositing a liner using a relatively shorter radiofrequency power duration compared to the example of FIG. 1B.

FIG. 3 schematically shows a structure formed by depositing a liner using a relatively longer radiofrequency power duration compared to the example of FIG. 1B.

FIGS. 4A-4C show a flow diagram illustrating an example method of partially filling a gap by forming a liner in a first portion of the gap, and then depositing silicon oxide in a second portion of the gap.

FIG. 5 shows a block diagram of an example ALD processing tool.

FIG. 6 shows a block diagram illustrating an example computing system.

### DETAILED DESCRIPTION

The term “aspect ratio” generally represents a ratio between a depth of a substrate feature and an average width of the feature. An example substrate feature is a gap.

The term “atomic layer deposition” (ALD) generally represents a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth”, “deposition”, and variants thereof, also can be used to refer to film formation.

The term “ALD cycle” generally represents a sequence of processes used to form a layer of a film in an ALD process.

The terms “ALD cycle comprising an inhibitor” and “inhibited ALD cycle” generally represent an ALD cycle that includes introduction of an inhibitor to a processing chamber during the cycle.

The term “ALD tool” generally represents a machine comprising a processing chamber and other hardware configured to perform ALD processing.

The term “chemical vapor deposition” (CVD) generally represents a process in which a solid phase film is formed on a substrate by directing a flow of one or more precursor gases over the substrate surface under conditions configured to cause the film formation. Plasma enhanced chemical vapor deposition (PECVD) utilizes a plasma to facilitate the film formation.

The term “conformal film” generally represents a film having a consistent thickness on substrate surfaces of different orientations.

The term “flow control hardware” generally represents components that fluidly connect one or more chemical sources with a processing chamber. Flow control hardware can comprise one or more mass flow controllers and/or valves, for example.

The term “gap” generally represents a recess in a substrate surface. Examples of gaps can include trenches, holes, and vias. When referring to a gap, the term “first portion” generally represents a region of the gap extending from the top of the gap to a selected depth within the gap. The term “second portion” generally represents a region of the gap extending from the selected depth to the bottom of the gap.

The term “gap fill” generally represents a process that fills a gap on a substrate with a material. The term “partial gap fill” generally represents a process that partially fills a gap from a bottom of the gap to a selected depth within the gap.

The term “inhibitor” generally represents a compound that can be introduced into a processing chamber, that can adsorb to a substrate surface, and that inhibits ALD growth of an oxide film when adsorbed to the substrate surface. Suitable inhibitors for inhibiting ALD growth of an oxide film include halogen-containing inhibitors, carbon-containing inhibitors, and nitrogen-containing inhibitors. The term “inhibitor” is used to represent the inhibitor molecule, reactive inhibitor species generated by introducing the inhibitor molecule into a plasma, and inhibitor species adsorbed to a substrate surface.

Examples of nitrogen-containing inhibitors can include nitrogen (N₂), ammonia (NH₃), nitrogen and hydrogen mixtures, amines, diamines, and aminoalcohols.

Examples of halogen-containing inhibitors can include fluorine-containing inhibitors, chlorine-containing inhibitors, bromine-containing inhibitors, and iodine-containing inhibitors. Examples of fluorine-containing inhibitors can include molecular fluorine (F₂), hydrogen fluoride (HF), boron trifluoride (BF₃), phosphorus trifluoride (PF₃), nitrogen trifluoride (NF₃), chlorine trifluoride (ClF₃), chlorine pentafluoride (ClF₅), and chalcogen fluorides such as sulfur tetrafluoride (SF₄) and sulfur hexafluoride (SF₆). Further examples of fluorine-containing inhibitors can include chlorofluorocarbons such as trichlorofluoromethane (CCl₃F), fluorocarbons such as carbon tetrafluoride (CF₄) or hexafluoroethane (C₂F₆), and hydrofluorocarbons such as difluoromethane (CH₂F₂). Further examples of chlorine-containing inhibitors can include chalcogen chlorides such as sulfur monochloride (S₂Cl₂) and sulfur dichloride (SCl₂). Further examples of halogen-containing inhibitors can include chlorine (Cl₂), hydrogen chloride (HCl), carbon tetrachloride (CCl₄), bromine (Br₂), hydrogen bromide (HBr), iodine (I₂), hydrogen iodide (HI), and 1,2-diiodoethane (C₂H₄I₂).

Examples of suitable carbon-containing inhibitors can include alkanes, alkenes, alkynes, cyclic hydrocarbons, aromatics, alcohols, aldehydes, esters, ethers, ketones, aldehydes, alkyl halides, alkyl amines, and alkyl diamines. In some examples, the carbon-containing inhibitor can comprise an alkane comprising a general formula CₙH₂ₙ₊₂ in which n=1 to 10. Examples of suitable alkanes can include methane, ethane, propane, butane, pentane, hexane, and substituted alkanes. Other examples of carbon-containing inhibitors can include an alkene, an alkyne, a cyclic hydrocarbon, an aromatic, an alcohol, a diol, an aldehyde, an ester, an ether, a ketone, an alkyl halide, an alkyl amine, or an alkyl diamine. In still other examples, the carbon-containing inhibitor can include a mixture of carbon-containing inhibitors. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutene, cyclopentane and cyclohexane. Examples of suitable aromatics can include benzene, toluene, pyridine, and pyrimidine. Examples of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Examples of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, and piperidine. Examples of suitable alkyl diamines can include ethylenediamine and 1,3-diaminopropane.

The term “liner” generally represents a sub-conformal layer of a film deposited in a gap to inhibits or prevents oxide film growth. A liner can comprise a film of silicon nitride (Si₃N₄), silicon carbon nitride (SiC₍₁₋ₓ₎N_{(1.333x)}, 0<x<1, hereinafter SiCN), silicon carbide (SiC), or silicon oxynitride (SiOₓN_{y}, 0≤x≤2, 0≤y≤1.33, hereinafter SiON), for example.

The term “metal-containing precursor” generally represents any material that can be introduced into a processing chamber in a gas phase to form a metal oxide film on a substrate. Examples of such metal-containing precursors include aluminum-containing precursors, gallium-containing precursors, titanium-containing precursors, vanadium-containing precursors, zinc-containing precursors, zirconium-containing precursors, hafnium-containing precursors, and tungsten-containing precursors, which respectively may be used to form aluminum oxide (Al₂O₃), gallium oxide (Ga₂O₃), titanium dioxide (TiO₂), vanadium dioxide (VO₂), zinc oxide (ZnO), zirconium dioxide (ZrO₂), hafnium dioxide (HfO₂), and tungsten trioxide (WO₃).

Examples of aluminum-containing precursors can include trimethylaluminum (Al(CH₃)₃).

Examples of titanium-containing precursors can include titanium tetrachloride (TiCl₄) and titanium isopropoxide (Ti(OCH(CH₃)₂)₄).

Examples of vanadium-containing precursors can include tetrakis(ethylmethylamido)vanadium (IV).

Examples of zinc-containing precursors can include diethylzinc ((C₂H₅)₂Zn).

Examples of zirconium-containing precursors can include tetrakis(dimethylamido)zirconium (IV).

Example hafnium-containing precursors can include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Examples of tungsten-containing precursors can include tungsten hexafluoride (WF₆), tungsten hexachloride (WCl₆), and tungsten hexacarbonyl (W(CO)₆).

The term “nonconformal” generally represents a film comprising an uneven thickness.

The term “oxidant” generally represents a gas species containing oxygen available for reacting with a film precursor to form an oxide film. Examples of oxidants comprise molecular oxygen (O₂), water vapor (H₂O), hydrogen peroxide (H₂O₂), ozone (O₃), nitrous oxide (N₂O), and other nitrogen oxides.

The term “oxide film” generally represents a film deposited on a substrate surface that comprises oxygen and an oxidized species. Examples of oxide films comprise silicon-containing oxide films. Examples of silicon-containing oxide films include silicon dioxide (SiO₂), silicon oxynitride, and silicon oxycarbide (SiOₓC_{y}, 0≤x≤2, y=1-0.5x). Examples of oxide films also comprise metal oxide films such as aluminum oxide (Al₂O₃), gallium oxide (Ga₂O₃), titanium dioxide (TiO₂), vanadium dioxide (VO₂), zinc oxide (ZnO), zirconium dioxide (ZrO₂), hafnium dioxide (HfO₂), and tungsten trioxide (WO₃).

The term “oxide film precursor” generally represents a material that can be introduced into a processing chamber to form an oxide film on a substrate in the processing chamber. Examples of oxide film precursors include silicon-containing precursors that can be used to form silicon-containing oxide films. Example silicon-containing oxide films include silicon dioxide, silicon oxynitride, and silicon oxycarbide films. Examples of oxide film precursors further include metal-containing precursors that can be used to form metal oxide films.

The term “plasma” generally represents a gas comprising cations and free electrons. The term “in-situ plasma” generally represents a plasma to which a substrate is directly exposed during substrate processing.

The term “processing chamber” generally represents an enclosure in which chemical and/or physical processes are performed on substrates. The pressure, temperature and atmospheric composition within a processing chamber can be controllable to perform chemical and/or physical processes.

The terms “purge” and variants thereof generally represent processes in which unwanted species are removed from a processing chamber.

The term “silicon-containing precursor” generally represents any material that can be introduced into a processing chamber in a gas phase to form a silicon-containing film on a substrate. Example film precursors for forming silicon-containing films using PEALD can comprise materials having the general structure:

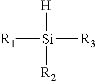

where R₁, R₂ and R₃ can be the same or different substituents, and can include silanes, siloxy groups, amines, halides, hydrogen, or organic groups, such as alkylamines, alkoxy, alkyl, alkenyl, alkynyl, and aromatic groups. Organosilanes can include any silicon-containing precursor comprising a carbon-containing functional group.

Example silicon-containing precursors include silane, polysilanes (H₃Si—(SiH₂)ₙ—SiH₃), where n≥0, such as disilane, trisilane, tetrasilane, and trisilylamine.

In some examples, the silicon-containing precursor is an alkoxysilane. Alkoxysilanes that can be used include those having a composition of Hₓ—Si—(OR)_{y}, where x=1-3, x+y=4 and each R is a substituted or unsubstituted alkyl, substituted or unsubstituted alkenyl, substituted or unsubstituted alkynyl, or substituted or unsubstituted aromatic group, and Hₓ(RO)_{y}, —Si—Si—(OR)_{y}Hₓ, is a substituted or unsubstituted alkyl, substituted or unsubstituted alkenyl, substituted or unsubstituted alkynyl, or substituted or unsubstituted aromatic group.

Examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor can be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

In some examples, the silicon-containing precursor can be an aminosilane. Example aminosilanes include bisdiethylaminosilane, diisopropylaminosilane, bis(t-butylamino) silane (BTBAS), di-sec-butylaminosilane, or tris(dimethylamino)silane (3DMAS). Aminosilane precursors can have the general formula: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

In some examples, the silicon-containing precursor can be a halosilane. Examples of halosilanes can include dichlorosilane (H₂SiCl₂), hexachlorodisilane (Si₂Cl₆), and diiodosilane (H₂SiI₂).

The term “sub-conformal layer” generally represents a conformal film that covers only part of a feature. For example, a sub-conformal film in a gap extends partway into the gap, covering a first portion of an interior surface of the gap and not covering a second portion of the interior surface of the gap, wherein the second portion is deeper within the gap than the first portion.

The term “substrate” generally represents any object on which a film can be deposited.

The term “substrate support” generally represents any structure for supporting a substrate in a processing chamber during substrate processing.

The term “3D NAND” is an abbreviation of three-dimensional NOT AND, and generally represents memory architecture based upon NOT AND logic gates.

The term “3D NOR” is an abbreviation of three-dimensional NOT OR, and generally represents memory architecture based upon NOT OR logic gates.

The term “3D DRAM” is an abbreviation of three-dimensional dynamic random access memory.

Atomic layer deposition (ALD) can be used to fill a gap on a substrate. ALD involves performing one or more deposition cycles to grow a thin film on a substrate surface in a layer-by-layer manner. Example films that can be grown using ALD include oxide films, such as silicon oxide films. Plasma enhanced ALD (PEALD) utilizes a plasma to facilitate deposition of a film. During a PEALD oxide film deposition cycle, a film precursor gas is introduced into a processing chamber and adsorbs onto a substrate as a self-limiting layer. Next, the processing chamber is purged to remove excess film precursor. Then, an oxidant is introduced to the processing chamber. While the oxidant is in the processing chamber, a plasma is formed. The plasma forms reactive oxygen species from the oxidant. The reactive oxygen species react with the adsorbed layer of film precursor to form a layer of the oxide film. Examples of oxide films that can be formed by ALD include films of silicon oxide (SiO₂), silicon oxynitride (SiOₓN_{y}), silicon oxycarbide (SiOₓC_{y}), aluminum oxide (Al₂O₃), gallium oxide (Ga₂O₃), titanium dioxide (TiO₂), vanadium dioxide (VO₂), zinc oxide (ZnO), zirconium dioxide (ZrO₂), hafnium dioxide (HfO₂), and tungsten trioxide (WO₃).

Due to the self-limiting layer-by-layer nature of ALD film growth, ALD can be used to form a highly conformal oxide film in a gap. However, in some applications, it may be desired to partially fill a gap in a bottom-up manner. For example, a process for forming a three-dimensional (3D) integrated circuit can include depositing a stack of alternating material layers, followed by forming a gap in the stack of alternating material layers. In some processes, it may be desired to cover layers in a lower portion of the gap below a selected depth in the gap with oxide, and not cover layers in an upper portion above the selected depth within the gap. The term “below the selected depth” refers to a region within the gap that is farther from an opening of the gap than the selected depth. The term “above the selected depth” refers to a region within the gap that is closer to the opening of the gap than the selected depth.

Performing a partial gap fill in a bottom-up manner can be challenging due to the conformal nature of ALD. One method is to deposit an inhibitor within the gap such that the inhibitor has a higher concentration on surfaces within the gap above the selected depth, and a lower concentration on surfaces of the gap below the selected depth. This can form a concentration gradient of inhibitor on the surfaces within the gap, with the inhibitor concentration decreasing with increasing depth in the gap. The higher concentration of inhibitor inhibits the deposition of the oxide film more strongly than the lower concentration of inhibitor. The use of an inhibitor in this manner can result in the deposition of a non-conformal oxide film having a tapered profile that is relatively thicker below the selected depth and relatively thinner above the selected depth. Then, an etching process can be performed to remove the oxide film from sidewall surfaces above the selected depth. However, the etching process can be time-consuming. Further, the etching process can remove film material from below the selected depth, where the film material is desired.

Accordingly, examples are disclosed that relate to performing a partial gap fill process in a bottom-up manner using ALD. Briefly, a liner is deposited sub-conformally in the gap. The liner can be deposited to cover surfaces in a first region of the gap extending from the top of the gap to a selected depth within the gap. Surfaces in a second region of the gap below the selected depth are not coated with the liner. Then, an inhibitor is deposited within the gap such that a higher concentration of inhibitor deposits in the first region of the gap, and a lower concentration of inhibitor deposits in the second region of the gap. The inhibitor can comprise a concentration gradient that decreases with increasing depth in the gap. In regions with the liner, the combination of the liner and inhibitor can prevent formation of the oxide film. Further, in regions below the liner, the concentration gradient of the inhibitor can cause higher rates of PEALD oxide film deposition at a bottom of the gap than closer to an opening of the gap. This can result in bottom-up oxide film growth. This also can help to avoid a post-oxide deposition etching step to remove oxide deposited in the first portion of the gap. In some examples, the liner alone can be used without an inhibitor to inhibit oxide film growth. The use of an inhibitor in combination with a liner can provide for a different oxide film profile as a function of depth than the use of a liner without an inhibitor.

The depth in the gap to which the liner is deposited can be controlled by a duration for which radiofrequency power is applied during liner deposition. As such, the disclosed examples can provide for control of a depth to which an oxide is deposited in a partial gap fill process.

The liner can comprise any suitable material that inhibits oxide film growth. In the case of a silicon oxide film, an example liner material is silicon nitride (Si₃N₄). Further examples of liner materials that can be used to inhibit silicon oxide film growth can include silicon carbon nitride (SiCN), silicon carbide (SiC), and silicon oxynitrides (SiON). Silicon nitride can cause a nucleation delay for reactions involving silicon oxide ALD film precursors. The term “nucleation delay” generally represents a period were physisorption and chemisorption of a molecule onto a surface does not occur. For example, applying an inhibitor to a surface can result in fewer reactive surface sites for a precursor/reactant to absorb. This can lead to no growth or reduced growth over a plurality of ALD cycles. Alternatively or additionally, some inhibiting molecules can induce a surface dipole. The surface dipole can repel the precursor molecule, reducing physisorption. Silicon nitride can cause a nucleation delay for the conversion of adsorbed aminosilane precursors to silicon oxide, thereby inhibiting growth of the silicon oxide. In contrast, less or no nucleation delay occurs on surfaces without the silicon nitride liner. When used in combination with a halogen-containing inhibitor, a silicon nitride liner can substantially prevent oxide film growth in regions within the gap that include the liner with adsorbed inhibitor. In the second portion of the gap, where the silicon nitride is not deposited, deposition of SiO₂ can occur.

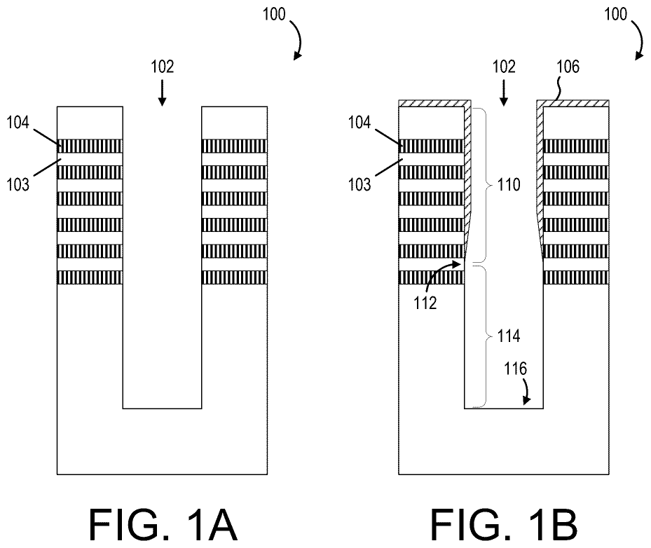

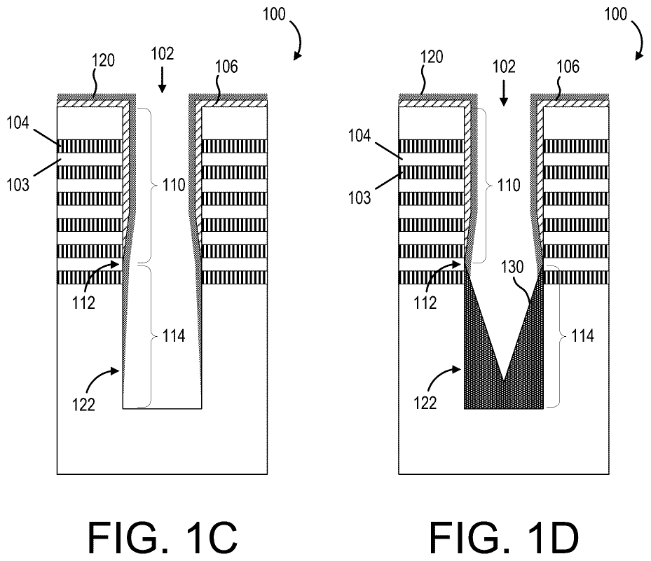

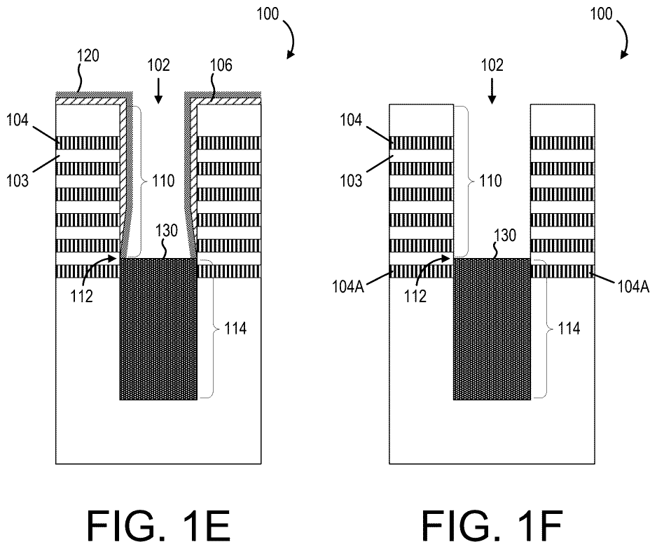

FIGS. 1A-1F schematically show substrate structures formed in an example partial gap fill process that utilizes a liner. The partial gap fill process includes depositing a sub-conformal layer of silicon nitride in a gap prior to partially filling the gap with silicon oxide. First, FIG. 1A shows a substrate 100 comprising a gap 102. The gap 102 can comprise any suitable aspect ratio. Examples include aspect ratios within a range of 1:1 to 250:1. The substrate 100 comprises an stack of alternating layers of a first material 103 and of a second material 104. Stacks of alternating material layers can be used to form 3D integrated circuits. Example 3D integrated circuits include 3D NAND memory, 3D NOR memory, and 3D DRAM. In the instance of 3D DRAM, the layers can comprise silicon alternating with silicon germanium (SiGe). In the case of 3D NAND memory, the layers can comprise silicon oxide alternating with polycrystalline silicon (polysilicon), or silicon oxide alternating with silicon nitride. Other examples of gaps include trenches, holes, and vias. For example, gaps can be used to form trench isolation regions in logic devices.

FIG. 1B shows substrate 100 after deposition of a liner 106 comprising a sub-conformal layer of silicon nitride. The liner 106 can be deposited using any suitable method. One example is PEALD. In a sub-conformal PEALD process, a film precursor is adsorbed onto surfaces of a feature. Example film precursors for forming a silicon nitride liner include silicon-containing precursors such as aminosilanes. Then a portion of the precursor is converted to the liner material. For example, a nitrogen-containing precursor can be introduced into a plasma to form reactive nitrogen-containing species. The reactive nitrogen containing species can then react with the adsorbed silicon-containing precursor to form silicon nitride. The plasma can be extinguished to stop generating reactive nitrogen-containing species prior to conversion of all adsorbed silicon-containing precursor to silicon nitride. Adsorbed silicon-containing precursor is converted to silicon nitride progressively from an opening of the gap toward a bottom of the gap. Thus, a depth within the gap to which the liner extends is a function of radiofrequency power duration.

In the depicted example, the liner 106 is deposited on the surface of substrate 100 and in a first portion 110 of gap 102. The first portion 110 extends from an opening of gap 102 to a selected depth 112 within the gap. The liner 106 is not deposited in a second portion 114 of the gap. The second portion extends from the selected depth 112 to a bottom 116 of the gap 102. The liner 106 can comprise any suitable thickness. Examples include thicknesses within a range of 3 to 100 Å. In some examples, the thickness of the liner 106 is in a range of 3-20 Å. In further examples, the thickness of the liner 106 is in a range of 3-5 Å. The use of a relatively thinner liner 106 can facilitate removal of the liner at a subsequent process step compared to the use of a relatively thicker liner.

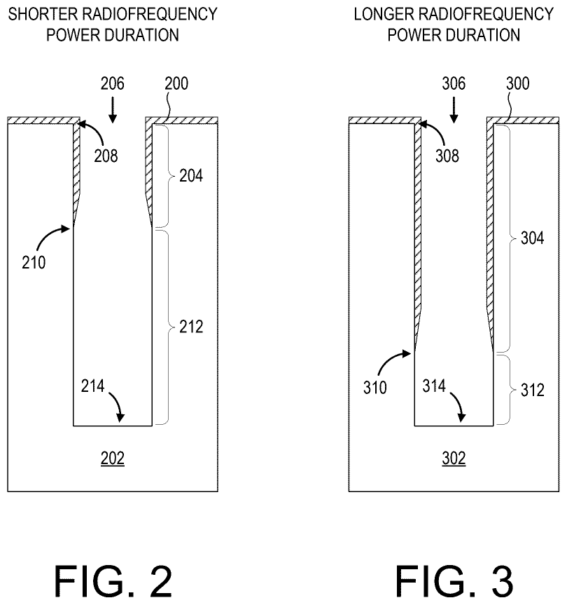

FIGS. 2-3 schematically show liners that demonstrate the relationship between radiofrequency power duration and a distance within a gap to which a silicon nitride liner extends. First, FIG. 2 shows an example liner 200 formed using a relatively shorter radiofrequency power duration compared to the example depicted in FIG. 3. In FIG. 2, the liner 200 comprises a sub-conformal layer of silicon nitride deposited on a substrate 202 in a first portion 204 of a gap 206. The first portion 204 extends from a top 208 of the gap 206 to a selected depth 210 within the gap 206. The liner 200 does not extend into a second portion 212 of the gap 206. The second portion 212 extends to a bottom 214 of the gap 206.

FIG. 3 shows an example liner formed using a relatively longer radiofrequency power duration than the example of FIG. 2. In FIG. 3, a liner 300 comprising a sub-conformal layer of silicon nitride is deposited on substrate 302 and in a first portion 304 of a gap 306. The first portion 304 extends from a top 308 of the gap 306 to a selected depth 310 within the gap 306. The selected depth 310 of FIG. 3 is farther from the opening of the gap 306 compared to the selected depth 210 of FIG. 2. The liner 300 is not deposited in a second portion 312 of gap 306. The second portion 312 extends from the selected depth 310 to a bottom 314 of the gap 306.

During a PEALD cycle, a longer duration of radiofrequency power allows reactive nitrogen species formed by the plasma to move deeper into the gap. This converts film precursor to silicon nitride film on sidewall surfaces deeper in the gap. By using a relatively longer radiofrequency power duration, the liner 300 of FIG. 3 achieves a selected depth 312 that is deeper within the gap compared to selected depth 210 of the liner 200 of FIG. 2.

Returning to FIG. 1C, after forming the liner 106, an inhibitor 120 optionally is deposited within the gap 102. The inhibitor 120 is deposited onto substrate 100 under conditions that cause the inhibitor to adsorb at a higher concentration in the first portion 110 of the gap and a lower concentration in the second portion 114 within the gap. For example, a concentration of the inhibitor deposited at selected depth 112 is greater than a concentration of the inhibitor deposited at a second depth 122 within gap 102. Second depth 122 is within the second portion 114 of the gap. Second depth 122 also is farther from the top of the gap than selected depth 112. The resulting concentration gradient can inhibit oxide film growth more strongly within the first portion 110 of the gap 102 and less strongly within the second portion 114 of the gap 102. Further, as mentioned above, the liner 106 comprising the adsorbed inhibitor 120 can prevent oxide growth. The combination of the inhibitor 120 and the liner 106 as shown in this example can help fill the second portion 114 of the gap 102 in a bottom-up manner.

The deposition of the inhibitor to form a concentration gradient of inhibitor within the gap can be controlled by controlling various processing conditions. Example processing conditions include total processing chamber pressure, partial pressure of the inhibitor, partial pressure of other gases (for example, a diluent gas), substrate temperature, gas flow rates, inhibitor gas flow duration, and plasma characteristics. For example, the use of an in-situ plasma to deposit inhibitor can cause directional effects that drive the inhibitor into a gap. In some examples, the in-situ plasma can comprise a higher frequency component and a lower frequency component. The higher frequency component can provide the activation energy to form reactive inhibitor species. The lower frequency component can be used to direct the reactive inhibitor species to the substrate.

In some examples, the higher frequency radiofrequency energy component can comprise a power in a range of 50-6000 W. Increasing the power of the higher frequency component can drive the inhibitor farther within the gap. The lower frequency RF energy component also can comprise a power in a range of 0-6500 W. Increasing the power of the lower frequency component also can used to drive inhibitor farther within the gap. Increasing the inhibition time, the inhibitor partial pressure, the total processing chamber pressure, and the inhibitor flow rate can also lead to more inhibitor deposited deeper within the gap.

In examples that utilize a silicon nitride liner, suitable inhibitors include halogen-containing inhibitors. Halogen-containing inhibitors can chemisorb to a liner to form a halogenated surface. For example, a fluorine-containing inhibitor can chemisorb to a silicon nitride liner to form a fluorinated silicon nitride surface. A fluorinated silicon nitride surface can more strongly inhibit, or even prevent, oxide film growth compared to an unmodified silicon nitride surface. In other examples, a carbon-containing inhibitor can be used. Carbon-containing inhibitors physisorb to substrate surfaces, and compete with oxidant when converting adsorbed silicon-containing precursor to oxide. In yet further examples, a nitrogen-containing inhibitor can be used.

In other examples, the use of an inhibitor can be omitted. For example, as mentioned above, nucleation reactions involving aminosilanes can have a nucleation delay on a silicon nitride surface. Thus, growth of silicon oxide on silicon nitride liner 106 can be sufficiently inhibited without use of an inhibitor for some use contexts.

FIG. 1D shows deposition of an oxide film 130 in second portion 114 of gap 102. In some examples, oxide film 130 comprises silicon oxide. In other examples, any other suitable oxide film can be used. Examples include silicon oxynitride, silicon oxycarbide, aluminum oxide (Al₂O₃), gallium oxide (Ga₂O₃), titanium dioxide (TiO₂), vanadium dioxide (VO₂), zinc oxide (ZnO), zirconium dioxide (ZrO₂), hafnium dioxide (HfO₂), and tungsten trioxide (WO₃). The oxide film can be deposited using any suitable method. Examples include TALD and PEALD. Inhibitor 120 can be reapplied in one or more inhibited ALD cycles if needed.

Oxide film growth occurs at a relatively lower rate on surfaces with a greater concentration of deposited inhibitor and at a relatively higher rate on surfaces with a lesser concentration of deposited inhibitor. Thus, as depicted in FIG. 1D, growth of oxide film 130 is relatively slower at the selected depth 112 within gap 102 and relatively faster at the second depth 122 within gap 102. Further, oxide film growth is fully inhibited on the liner 106 comprising the inhibitor 120. As a result, the oxide film 130 fills the second portion 114 of the gap 102 in a bottom-up manner.

FIG. 1E shows substrate 100 after additional growth of oxide film 130 has been performed to fill second portion 114 of gap 102. Due to liner 106, oxide film 130 does not grow in first portion 110 of gap 102. Thus, liner 106 helps achieve a partial gap fill of gap 102 with oxide film 130. FIG. 1E also shows the inhibitor 120 prior to removal. In some examples, a passivation process can be used to remove the inhibitor. Where a halogen-containing inhibitor or a nitrogen-containing inhibitor is used, example passivation steps can comprise exposing the inhibitor adsorbed to the substrate surface to one or more of H₂ or O₂. In some examples, thermal and/or plasma energy can be used to facilitate the passivation. Another example passivation involves exposing the inhibitor to a plasma comprising H₂/N₂/Ar. In other examples, the inhibitor can be consumed over the course of the ALD process. In such examples, additional inhibited ALD cycles can be used as necessary to form an oxide film of a desired profile.

FIG. 1F shows substrate 100 after removal of liner 106. Liner 106 can be removed by a suitable etching process. Examples can include dry etch and wet etch processes. For example, a fluorine-containing gas (for example, NF₃, SF₆, or CF₄) can be used with a plasma to remove a silicon nitride liner. In other examples, a wet etch using phosphoric acid can be used to selectively etch silicon nitride over silicon oxide. As mentioned above, in some examples, the liner 106 can comprise a thickness of 3 to 100 Å. A relatively thin liner can facilitate removal, as etch times can be relatively shorter than etch times for relatively thicker liners. In other examples, liner 106 is not removed, but instead is left in gap 102. Thus, by controlling the selected depth of the liner through control of radiofrequency power duration, a gap can be partially filled in a bottom-up manner to a controllable depth level.

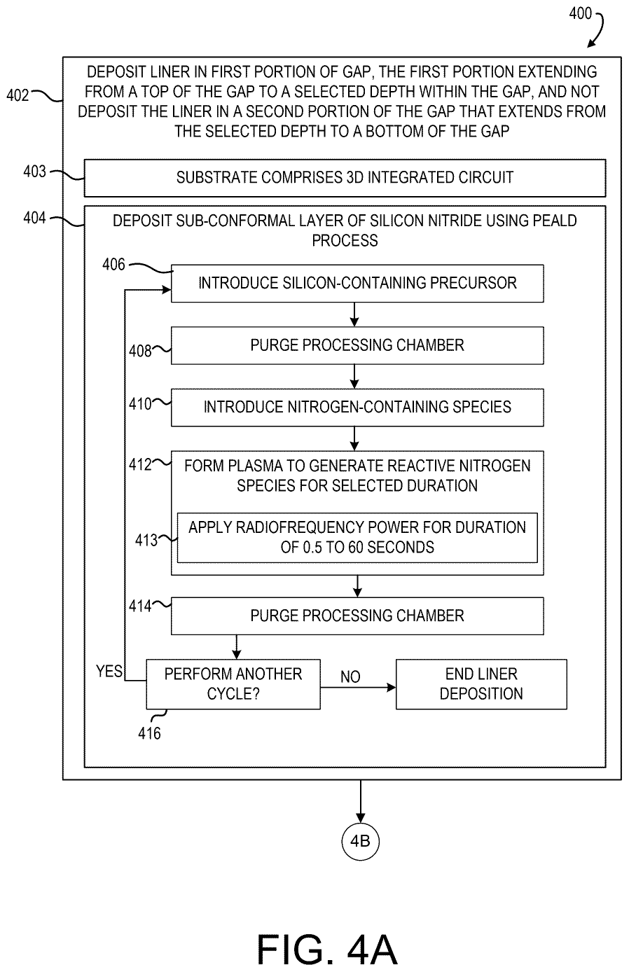

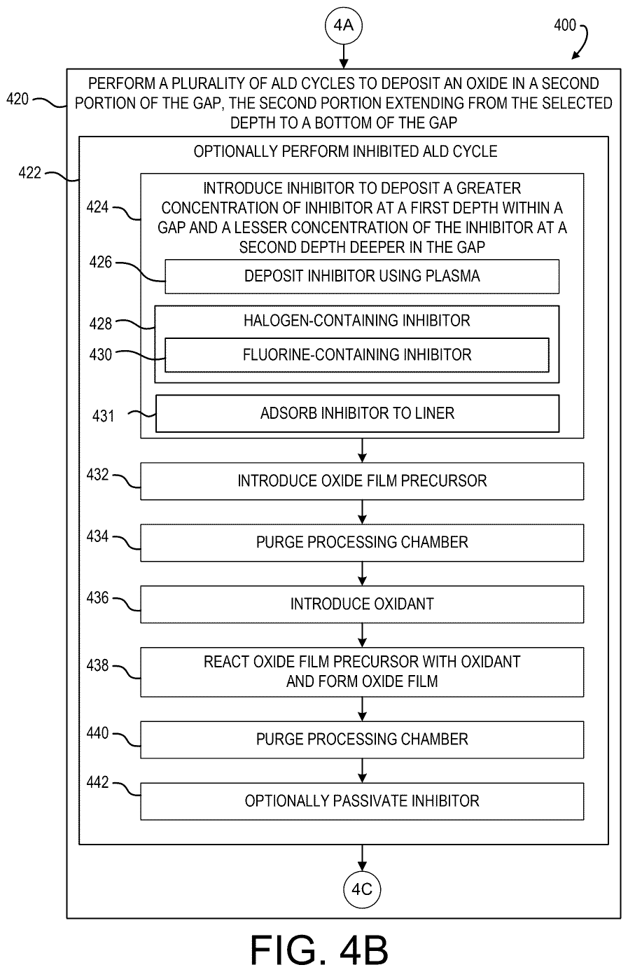

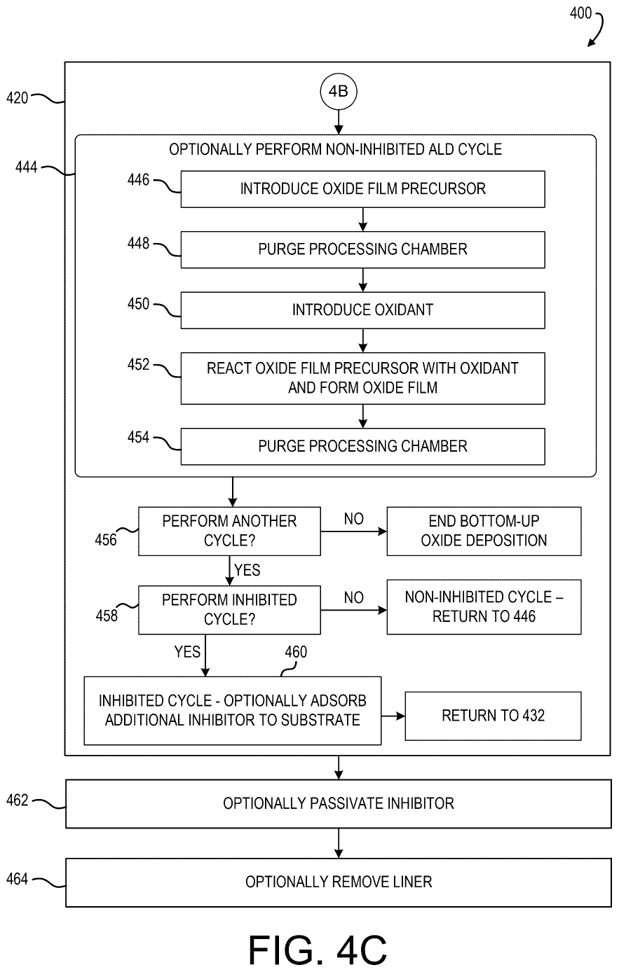

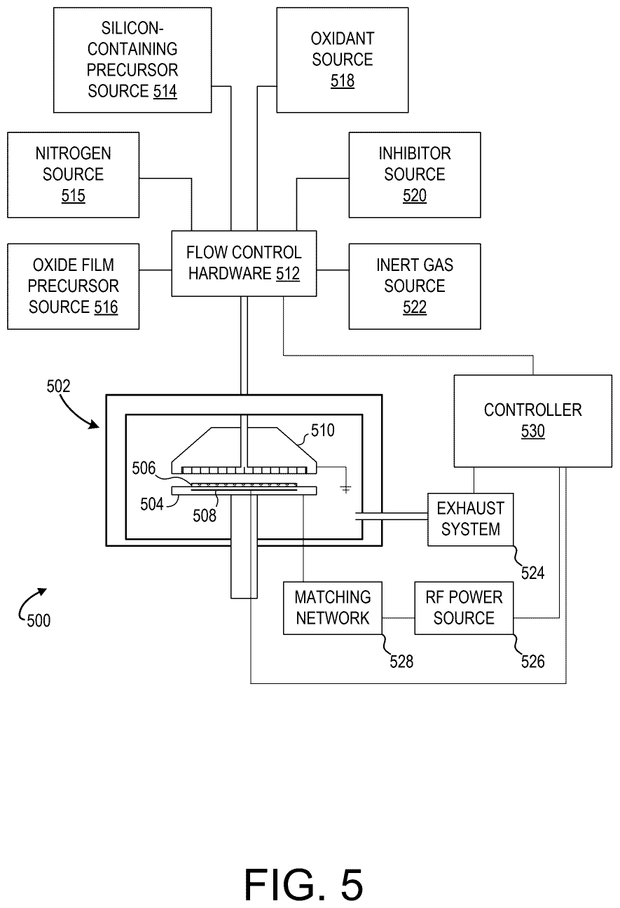

FIGS. 4A-4C show an example method 400 for performing a bottom-up partial gap fill process to partially fill a gap on a substrate. Method 400 can be performed using any suitable ALD tool. An example ALD tool is described below with reference to FIG. 5.

First referring to FIG. 4A, at step 402, method 400 comprises depositing a liner in a first portion of the gap and not depositing the liner in a second portion of the gap. The first portion extends from a top of the gap to a selected depth within the gap. The second portion of the gap extends from the selected depth to a bottom of the gap. In some examples, as indicated at 403, the substrate comprises a 3D integrated circuit. Substrate 100 is an example of a 3D integrated circuit. In other examples, a liner can be formed on any other suitable structure in an integrated circuit manufacturing process.

In some examples, the liner comprises a sub-conformal layer of silicon nitride. In such examples, the liner can be deposited using a PEALD process, as indicated at step 404. Depositing a silicon nitride liner using PEALD can comprise, at step 406, introducing a silicon-containing precursor into a processing chamber comprising a substrate. The silicon-containing precursor adsorbs onto surfaces in a gap on the substrate. Suitable silicon-containing precursors for forming silicon nitride can include aminosilanes. Example aminosilanes include bisdiethylaminosilane, diisopropylaminosilane, bis(t-butylamino) silane, di-sec-butylaminosilane, or tris(dimethylamino)silane. In some examples, trisilylamine, halosilanes, and/or organosilanes can be used. Examples of halosilanes can include dichlorosilane (H₂SiCl₂), hexachlorodisilane (Si₂Cl₆), and diiodosilane (H₂SiI₂). Examples of organosilanes are listed above.

At step 408, the processing chamber is purged to remove excess silicon-containing precursor. Continuing, at step 410, method 400 comprises introducing a nitrogen-containing species into the processing chamber. The nitrogen-containing species is used to generate reactive nitrogen species in a plasma to convert adsorbed silicon-containing precursor to silicon nitride. Reactive nitrogen species can include excited state N₂ and/or nitrogen radicals, for example. In some examples, the nitrogen-containing species is nitrogen gas. In other examples, the nitrogen-containing species can comprise NH₃, nitrogen and hydrogen mixtures, or hydrazine (N₂H₄).

Continuing, at step 412, method 400 includes forming a plasma for a selected duration to produce reactive nitrogen species. The reactive nitrogen species react with the adsorbed silicon-containing precursor to form the silicon nitride liner. As described above with regard to FIGS. 2 and 3, the duration for which the plasma is formed can control how far into the gap the silicon nitride liner extends. In some examples, at 413, forming the plasma comprises applying radiofrequency power for a duration of 0.5 to 60 seconds. In some examples, the duration is in a range of 1 to 30 seconds, or even a range of 1 to 20 seconds. In other examples, radiofrequency power can be applied for a duration outside of these ranges.

In some examples, the plasma comprises a radiofrequency plasma. The plasma can be capacitively coupled or inductively coupled plasma, for example. Examples frequencies for the radiofrequency plasma include frequencies of 400 MHz, 13.56 MHz, 27 MHz, 60 MHz, and 90 MHz. In other examples, a microwave plasma can be used instead of a radiofrequency plasma. Further, in some examples, the substrate is heated using a substrate heater during liner deposition.

In some examples, at step 414, a purge is performed following the plasma process of step 410 to complete the ALD cycle. Such a purge can be performed after extinguishing the plasma. In other examples, a purge can be omitted.

At step 416, it is determined whether any additional ALD cycles are to be performed to form the liner. If additional ALD cycles are to be performed, then the method 400 returns to step 406. On the other hand, if no more ALD cycles are to be performed to form the liner, then the liner deposition process ends. While described above with regard to the formation of a silicon nitride liner, in other examples other suitable liner materials can be used. Examples include silicon carbide, silicon carbon nitride, and silicon oxynitride.

Referring next to FIG. 4B, after depositing the liner, method 400 comprises, at step 420, performing a plurality of oxide ALD cycles to deposit an oxide in a second portion of the gap. The second portion of the gap extends from the selected depth to a bottom of the gap. The plurality of ALD cycles can comprise inhibited ALD cycles and/or non-inhibited ALD cycles.

With regard to inhibited ALD cycles, an inhibitor can be deposited to help further inhibit oxide film formation in regions where the liner is deposited. In some such examples, the combination of the liner and the inhibitor adsorbed on the liner can fully prevent oxide film formation on the inhibited liner surfaces. Thus, at step 422, method 400 comprises optionally performing an inhibited ALD cycle. An inhibited ALD cycle to deposit a layer of oxide comprises, at 424, introducing an inhibitor into the processing chamber in such a manner as to deposit a greater concentration of the inhibitor at a first depth within the gap and a lesser concentration of the inhibitor at a second depth in the gap. The second depth is deeper than the first depth, with reference to an opening of the gap. As indicated at 426, in some examples the inhibitor can be deposited using a plasma. As described above, various deposition conditions can be controlled to deposit the inhibitor to have a greater concentration at the first depth and a lesser concertation at the second depth. Example processing conditions that can be varied to vary a concentration profile of inhibitor deposited within a gap as a function of depth in the gap include total processing chamber pressure, partial pressure of the inhibitor, partial pressure of other gases (for example, a diluent gas), substrate temperature, gas flow rates, inhibitor gas flow duration, and plasma characteristics.

Any suitable inhibitor can be used. Examples include halogen-containing inhibitors, as indicated at 428. Suitable halogen-containing precursors can include fluorine-containing inhibitors, as indicated at 430. Example fluorine inhibitors can include F₂, HF, BF₃, PF₃, NF₃, a chlorofluorocarbon, a fluorocarbon, a hydrofluorocarbon, a chalcogen fluoride such as SF₄ or SF₆, or an interhalogen such as ClF₃ or ClF₅. Example fluorocarbons include CF₄ and C₂F₆. In other examples, a chlorine-containing precursor, bromine-containing precursor, or iodine-containing precursor can be used. Examples of chlorine-containing precursors include chalcogen chlorides such as S₂Cl₂ or SCl₂. In some examples, an interhalogen can be used. The term “interhalogen” generally represents a molecule comprising two or more different halogen atoms. In other examples, a nitrogen-containing inhibitor can be used. Examples of nitrogen-containing inhibitors include N₂, NH₃, nitrogen and hydrogen mixtures, amines, diamines, and aminoalcohols. In yet other examples, a carbon-containing inhibitor can be used. Examples include alkanes, alkenes, alkynes, cyclic hydrocarbons, aromatics, alcohols, aldehydes, esters, ethers, ketones, aldehydes, alkyl halides, alkyl amines, and alkyl diamines that are gas phase under processing conditions.

The plasma converts the inhibitor to reactive inhibitor species. The reactive inhibitor species can adsorb to surfaces on the substrate. For example, the inhibitor can adsorb to the liner, as indicated at 431. In other examples, the inhibitor is deposited without a plasma. Examples of inhibitors that can be deposited without a plasma include carbon-containing inhibitors. As described above, carbon-containing inhibitors can physisorb to a substrate surface. The physisorbed carbon-containing inhibitors compete with the silicon-containing precursor for oxygen during the oxidation of the silicon-containing precursor. Thus, a higher concentration of carbon-containing precursor reduces an amount of oxygen available for oxidizing the silicon-containing precursor.

Continuing, at 432, inhibited ALD cycle 422 comprises introducing an oxide film precursor into the processing chamber. Example film precursors for forming silicon-containing films using PEALD can comprise materials having the general structure:

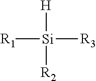

where R₁, R₂ and R₃ can be the same or different substituents, and can include silanes, siloxy groups, amines, halides, hydrogen, or organic groups, such as alkylamines, alkoxy, alkyl, alkenyl, alkynyl, and aromatic groups.

Example silicon-containing precursors include silane, polysilanes (H₃Si—(SiH₂)ₙ—SiH₃), where n≥0, such as disilane, trisilane, tetrasilane, and trisilylamine.

In some examples, the silicon-containing precursor is an alkoxysilane. Alkoxysilanes that can be used include those having a composition of Hₓ—Si—(OR)_{y}, where x=1-3, x+y=4 and each R is a substituted or unsubstituted alkyl, substituted or unsubstituted alkenyl, substituted or unsubstituted alkynyl, or substituted or unsubstituted aromatic group, and Hₓ(RO)_{y}, —Si—Si—(OR)_{y}Hₓ, is a substituted or unsubstituted alkyl, substituted or unsubstituted alkenyl, substituted or unsubstituted alkynyl, or substituted or unsubstituted aromatic group.

Examples of silicon-containing precursors include tetraethyl orthosilicate, tetramethoxysilane, methylsilane, trimethylsilane, ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane, diethoxysilane, dimethoxymethylsilane, dimethoxysilane, methyl-diethoxysilane, methyl-dimethoxysilane, t-butoxydisilane, triethoxysilane, and trimethoxysilane.

In some examples, the silicon-containing precursor can be a siloxane. Example siloxanes include octamethylcyclotetrasiloxane, octamethoxydodecasiloxane, tetramethylcyclotetrasiloxane, triethoxysiloxane, and tetraoxymethylcyclotetrasiloxane.

In some examples, the silicon-containing precursor can be an aminosilane. Example aminosilanes include bisdiethylaminosilane, diisopropylaminosilane, bis(t-butylamino) silane, di-sec-butylaminosilane, or tris(dimethylamino)silane. Aminosilane precursors can have the general formula: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

In other examples, the oxide film precursor can comprise a metal-containing precursor. Examples of metal-containing precursors include aluminum-containing precursors, gallium-containing precursors, titanium-containing precursors, vanadium-containing precursors, zinc-containing precursors, zirconium-containing precursors, hafnium-containing precursors, and tungsten-containing precursors.

At step 434, the processing chamber is purged to remove excess oxide film precursor. Next, the inhibited ALD cycle 422 comprises introducing an oxidant into the processing chamber at 436. Suitable oxidants include O₂, O₃, H₂O, H₂O₂, N₂O, and other nitrogen oxides. At 438, the inhibited ALD cycle 422 comprises reacting the adsorbed oxide film precursor with the oxidant to form a layer of oxide film on the substrate. In examples that utilize PEALD to form the oxide film, a plasma is used to react the oxide film precursor with the oxidant. For example, the reaction can be performed using a radiofrequency power source to form a plasma comprising the oxidant. The radiofrequency power source can be operated at any suitable frequency and power. Examples include those listed above. The oxidant can be converted to oxygen-containing reactive species via the plasma. The oxygen-containing reactive species can then react with the adsorbed monolayer of oxide film precursor to form a layer of oxide film on the substrate. Suitable oxide films include silicon dioxide, silicon oxynitride, and silicon oxycarbide films. Due to the inhibitor deposited at 424, the oxide film grows nonconformally. As such, a relatively thicker oxide film layer can be formed on a surface in the gap at the second depth corresponding to the lesser concentration of inhibitor. Likewise, a relatively thinner oxide film layer can be formed on a surface in the gap at the selected depth corresponding to the greater concentration of inhibitor.

After reacting the oxide film precursor with the oxidant, the inhibited ALD cycle 422 comprises purging the processing chamber at 440. The inhibited ALD cycle 422 optionally can comprise passivating the inhibitor, at 442.

Referring next to FIG. 4C, method 400 comprises optionally a non-inhibited ALD cycle 444. In examples that omit the use of an inhibitor, all of the plurality of ALD cycles can comprise non-inhibited ALD cycle 444. In examples that use an inhibitor, a subset of ALD cycles can be non-inhibited ALD cycles 444, such as where the inhibitor is not fully consumed each ALD cycle.

An example non-inhibited ALD cycle 444 is as follows. At 446, the non-inhibited ALD cycle 444 comprises introducing an oxide film precursor into the processing chamber. As described above with regard to the inhibited ALD cycle 422, suitable oxide film precursors for forming silicon-containing oxide films can include polysilanes, aminosilanes, halosilanes, siloxanes, and organosilanes. In other examples, the oxide film precursor can comprise a metal-containing precursor. Example metal-containing precursors are described above. Next, at step 448, the processing chamber is purged to remove excess oxide film precursor.

Continuing, at 450, the non-inhibited ALD cycle 444 comprises introducing an oxidant into the processing chamber. Any suitable oxidant that can react with the oxide film precursor to form an oxide film can be used. Suitable oxidants include O₂, O₃, H₂O, and H₂O₂.

At 452, the non-inhibited ALD cycle 444 comprises, at step 452, reacting the oxide film precursor with the oxidant to form a layer of oxide film on the substrate. In examples that utilize PEALD, a plasma can be used to form reactive oxidant species that react with the film precursor. Where a liner is deposited in a first portion of a gap, oxide film formation is inhibited and/or prevented in the first portion of the gap. On the other hand, oxide film growth occurs in a second portion of the gap that has no liner. In other examples, an ALD cycle can be performed using TALD. In such examples, the reaction at step 452 is performed using thermal energy. The substrate also can be heated during a PEALD cycle. In some examples, a purge is performed at step 454 after reacting the oxide to complete the ALD cycle. In other examples, a purge can be omitted.

Continuing, at step 456, after optionally performing an inhibited ALD cycle 422 or a non-inhibited ALD cycle 446, method 400 comprises determining whether to perform another ALD cycle. If it is determined not to perform another ALD cycle, then the bottom-up oxide deposition cycle of method 400 ends. On the other hand, if it is determined to perform another ALD cycle, then method 400 comprises, at step 458, determining whether to perform an inhibited ALD cycle. If the next cycle is an inhibited ALD cycle, then method 400 comprises, at 460, optionally adsorbing additional inhibitor to the substrate (as described with reference to step 424). Then, method 400 returns to step 432. If the next cycle is a non-inhibited ALD cycle, then method 400 returns to 446.

After completing the bottom-up oxide deposition, method 400 optionally comprises passivating any inhibitor remaining on the substrate at step 462. Method 400 further optionally comprises removing the liner at step 464. Any suitable etching method can be used to remove the liner. Examples can include wet etching and dry etching processes. As the liner can be thin (e.g., 3 to 100 Å), etch times can be relatively short. In other examples, removal of the liner can be omitted.

FIG. 5 shows a schematic view of an example ALD tool 500 for performing atomic layer deposition. The ALD tool 500 is configured at a PEALD tool. The ALD tool 500 is an example of a processing tool that can implement the methods described above with reference to FIGS. 1A-4C. In some examples, the ALD tool 500 can be used to deposit both a liner and an oxide film. In other examples, deposition of a liner and deposition of an oxide film can be performed using separate tools. In other examples, a liner and/or an oxide film according to the disclosed examples can be deposited in a TALD chamber.

ALD tool 500 comprises a processing chamber 502 and a substrate support 504 within the processing chamber. The substrate support 504 is configured to support a substrate 506 disposed within the processing chamber 502. The substrate support 504 can comprise a pedestal, a chuck, and/or any other suitable structure. The substrate support 504 comprises a substrate heater 508. In other examples, a heater can be omitted, or can be located elsewhere within processing chamber 502.

The ALD tool 500 further comprises a showerhead 510. In other examples, a processing tool can comprise a nozzle or other apparatus for introducing gas into processing chamber 502, as opposed to or in addition to a showerhead. The ALD tool 500 further comprises flow control hardware 512. The flow control hardware 512 connects processing gas source(s) to the processing chamber. In the depicted example, the flow control hardware 512 connects a silicon-containing precursor source 514, a nitrogen source, an oxide film precursor source 516, an oxidant source 518, an inhibitor source 520, and an inert gas source 522 to the processing chamber. The flow control hardware 512 can include any suitable components. Examples include mass flow controllers, valves, and conduits.

The silicon-containing precursor source 514 comprises any suitable silicon-containing precursor for forming a sub-conformal layer of silicon nitride. Examples include aminosilanes, such as bisdiethylaminosilane, diisopropylaminosilane, bis(t-butylamino) silane, di-sec-butylaminosilane, or tris(dimethylamino)silane. Aminosilane precursors include the following: Hx-Si—(NR)y, where x=1-3, x+y=4, and R is a substituted or unsubstituted alkyl, alkenyl, alkynyl or aromatic group or hydride group. Suitable silicon-containing precursor also can include polysilanes, halosilanes and organosilanes.

The nitrogen source 515 comprises a source of nitrogen for use in forming a plasma comprising radical nitrogen species. Such a plasma can be used, for example, to activate silicon-containing precursor adsorbed on the substrate 506 to form a silicon nitride film in a first portion of a gap on the substrate. Example sources of nitrogen comprise N₂, NH₃ and N₂H₄.

The oxide film precursor source 516 can comprise any suitable oxide-film precursor that, when reacted with the oxidant, forms an oxide film. Example silicon-containing oxide films include silicon dioxide, silicon oxynitride, and silicon oxycarbide. For such films, example silicon-containing precursors include those listed above with reference to FIGS. 4B and 4C. In some examples, a same silicon-containing precursor can be used to provide precursor for a silicon nitride liner and a silicon oxide film.

The oxidant source 518 comprises any suitable species that can react with a silicon-containing precursor to form silicon oxide. Examples include O₂, O₃, H₂O, and H₂O₂, N₂O, other nitrogen oxides, and mixtures of two or more thereof.

The inhibitor source 520 comprises any suitable inhibitor that can adsorb to the substrate and inhibit growth of an oxide film in an ALD process. Suitable inhibitors can include halogen-containing inhibitors (e.g., fluorine-containing inhibitors, chlorine-containing inhibitors, bromine-containing inhibitors, iodine-containing inhibitors, interhalogens), nitrogen-containing inhibitors, and carbon-containing inhibitors. Suitable fluorine-containing inhibitors can include F₂, HF, BF₃, PF₃, NF₃, chlorofluorocarbons, fluorocarbons, hydrofluorocarbons, chalcogen fluorides, and interhalogens that are in gas phase under processing conditions. Examples of chlorofluorocarbons include CCl₃F. Examples of fluorocarbons include CF₄ and C₂F₆. Examples of hydrofluorocarbons include difluoromethane (CH₂F₂). Examples of chalcogen fluorides include SF₄ and SF₆. Examples of chalcogen chlorides include S₂Cl₂ and SCl₂. Examples of interhalogens include ClF₃ and ClF₅. Further examples of halogen-containing inhibitors can include Cl₂, HCl, CCl₄, Br₂, HBr, I₂, HI, and C₂H₄I₂.

Suitable nitrogen-containing inhibitors can include N₂, NH₃, nitrogen and hydrogen mixtures, amines, diamines, and aminoalcohols.

Suitable carbon-containing inhibitors can include compounds that can are gas-phase under processing conditions, that physisorb to the substrate 506, and can be oxidized by the oxidant to form gas-phase products. Example carbon-containing inhibitors suitable for use for nonconformal film deposition can comprise various alkanes, alkenes, alkynes, cyclic hydrocarbons, aromatics, alcohols, aldehydes, esters, ethers, ketones, aldehydes, alkyl halides, alkyl amines, and alkyl diamines. More specific examples of carbon-containing inhibitors include those listed above.

The inert gas source 522 can comprise any suitable inert gas. Examples include helium, neon, argon, krypton, xenon, and nitrogen. In some examples, one or more additional purge gas sources can be included, each providing a different purge gas. In other examples, the inert gas source 522 can be omitted and the nitrogen source 515 can be used for supplying inert gas.

The flow control hardware 512 can be controlled to flow gas from the silicon-containing precursor source 514, the nitrogen source 515, the oxide film precursor source 516, the oxidant source 518, the inhibitor source 520, and the inert gas source 522 into the processing chamber 502 through the showerhead 510. The flow control hardware 512 can comprise one or more valves controllable to place a selected gas source or selected gas sources in fluid connection with showerhead 510. The flow control hardware 512 also can comprise one or more mass flow controllers or other controllers for controlling a mass flow rate of gas.

The ALD tool 500 further comprises an exhaust system 524. The exhaust system 524 is configured to exhaust gases from the processing chamber 502. The exhaust system 524 can comprise any suitable hardware, including one or more low vacuum pumps and one or more high vacuum pumps.

The ALD tool 500 further comprises a radiofrequency power source 526 that is electrically connected to substrate support 504. Radiofrequency power source 526 is configured to form a plasma. When reacting adsorbed silicon-containing precursor with nitrogen, the radiofrequency power source 526 can form a plasma comprising the nitrogen. Similarly, when reacting adsorbed oxide film precursor with an oxidant, the radiofrequency power source 526 can form a plasma comprising the oxidant. In some examples, a halogen-containing inhibitor or a nitrogen-containing inhibitor is deposited on a substrate by forming a plasma comprising the inhibitor. The showerhead 510 is configured as a grounded opposing electrode in this example. In other examples, the radiofrequency power source 526 can supply radiofrequency power to showerhead 510, or to another suitable electrode structure.

The ALD tool 500 further includes include a matching network 528 for impedance matching of the radiofrequency power source 526. The radiofrequency power source 526 can be configured to provide RF energy of any suitable frequency and power. Examples frequencies include 400 kHz, 13.56 MHz, 27 MHz, 60 MHz, and 90 MHz. In some examples, the radiofrequency power source 526 is configured to operate at a plurality of different frequencies and/or powers. Examples of lower frequencies include frequencies of 3 MHz and below. The lower frequency radiofrequency energy component can comprise a power in a range of 0-6500 W. Examples of suitable high-frequency RF power includes frequencies within a range of 3 MHz to 300 MHz. The higher frequency radiofrequency energy component can comprise a power in a range of 50-6000 W. As described above, a duration for which radiofrequency power is applied can be controlled a selected depth within a gap on substrate 506 to which a deposited liner extends.

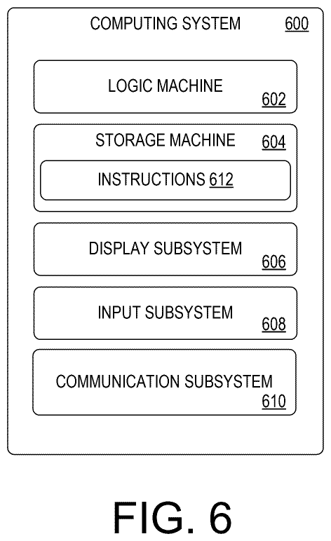

The controller 530 is operatively coupled to the substrate heater 508, the flow control hardware 512, the exhaust system 524, and the radiofrequency power source 526. The controller 530 is configured to control various functions of ALD tool 500 to perform a thin film deposition process, such as an ALD process. For example, the controller 530 is configured to operate the substrate heater 508 to heat a substrate to a desired temperature. The controller 530 also is configured to operate the flow control hardware 512 to flow a selected gas or mixture of gases at a selected rate into the processing chamber 502. The controller 530 is further configured to operate the exhaust system 524 to remove gases from processing chamber 502. The controller 530 can, for example, control the exhaust system 524 and/or the flow control hardware 512 to purge the processing chamber 502. The controller 530 is configured to operate the radiofrequency power source 526 for a selected duration to form a plasma, as well as to control any other suitable functions of ALD tool 500. The controller 530 can comprise any suitable computing system. Example computing systems are described below with reference to FIG. 6.

In some embodiments, the methods and processes described herein can be tied to a computing system of one or more computing devices. In particular, such methods and processes can be implemented as a computer-application program or service, an application-programming interface (API), a library, and/or other computer-program product.

FIG. 6 schematically shows a non-limiting embodiment of a computing system 600 that can enact one or more of the methods and processes described above. Computing system 600 is shown in simplified form. Computing system 600 can take the form of one or more personal computers, workstations, computers integrated with substrate processing tools, and/or network accessible server computers. Controller 530 is an example of computing system 600.

Computing system 600 includes a logic machine 602 and a storage machine 604. Computing system 600 can optionally include a display subsystem 606, input subsystem 608, communication subsystem 610, and/or other components not shown in FIG. 6.

Logic machine 602 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 604 includes one or more physical devices configured to hold instructions 612 executable by the logic machine to implement the methods and processes described herein. When such methods and processes are implemented, the state of storage machine 604 can be transformed—e.g., to hold different data.

Storage machine 604 can include removable and/or built-in devices. Storage machine 604 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 604 can include volatile, nonvolatile, dynamic, static, read/write, read-only, random-access, sequential-access, location-addressable, file-addressable, and/or content-addressable devices.

It will be appreciated that storage machine 604 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 602 and storage machine 604 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 606 can be used to present a visual representation of data held by storage machine 604. This visual representation can take the form of a graphical user interface (GUI). As the herein described methods and processes change the data held by the storage machine, and thus transform the state of the storage machine, the state of display subsystem 606 can likewise be transformed to visually represent changes in the underlying data. Display subsystem 606 can include one or more display devices utilizing virtually any type of technology. Such display devices can be combined with logic machine 602 and/or storage machine 604 in a shared enclosure, or such display devices can be peripheral display devices.

When included, input subsystem 608 can comprise or interface with one or more user-input devices such as a keyboard, mouse, or touch screen. In some embodiments, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 610 can be configured to communicatively couple computing system 600 with one or more other computing devices. Communication subsystem 610 can include wired and/or wireless communication devices compatible with one or more different communication protocols. As non-limiting examples, the communication subsystem can be configured for communication via a wireless telephone network, or a wired or wireless local- or wide-area network. In some embodiments, the communication subsystem can allow computing system 600 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for partially filling a gap in a substrate disposed in a processing chamber, the method comprising;
depositing a sub-conformal layer of silicon nitride in a first portion of the gap and not in a second portion of the gap, the first portion extending from a top of the gap to a selected depth within the gap, and the second portion extending from the selected depth to a bottom of the gap; and
performing a plurality of atomic layer deposition (ALD) cycles to deposit a silicon-containing oxide in the second portion of the gap, an ALD cycle of the plurality of ALD cycles comprising
exposing the substrate to a silicon-containing precursor to adsorb the silicon-containing precursor to a surface in the second portion of the gap, and
reacting the silicon-containing precursor with an oxidant to deposit the silicon-containing oxide on the surface in the second portion of the gap.

2. The method of claim 1, wherein an ALD cycle of the plurality of ALD cycles comprises exposing the substrate to an inhibitor under conditions configured to deposit the inhibitor into the gap such that a concentration of the inhibitor deposited at a first depth within the gap is greater than a concentration of the inhibitor deposited at a second depth within the gap, the second depth being within the second portion of the gap and the second depth being farther from the top of the gap than the first depth.

3. The method of claim 2, wherein exposing the substrate to the inhibitor comprises exposing the substrate to a halogen-containing inhibitor.

4. The method of claim 3, wherein the halogen-containing inhibitor comprises one or more of molecular fluorine, hydrogen fluoride, boron trifluoride, phosphorus trifluoride, nitrogen trifluoride, a chlorofluorocarbon, a fluorocarbon, a hydrofluorocarbon, a chalcogen fluoride, a chalcogen chloride, or an interhalogen.

5. The method of claim 1, further comprising removing the sub-conformal layer of silicon nitride from the first portion of the gap after depositing the silicon-containing oxide.

6. The method of claim 1, wherein depositing the sub-conformal layer of silicon nitride comprises exposing the substrate to one or more of a halosilane precursor or an aminosilane precursor, purging the processing chamber, and forming a plasma comprising reactive nitrogen species.

7. The method of claim 6, wherein forming the plasma comprises forming the plasma for a duration within a range of 0.5 to 60 seconds.

8. The method of claim 1, wherein the substrate comprises a stack of layers of silicon alternating with silicon germanium, a stack of layers of polysilicon alternating with silicon oxide, or a stack of layers of silicon nitride alternating with silicon oxide.

9. The method of claim 1, wherein the gap comprises a trench for forming a trench isolation region in a logic device.

10. A method for processing a substrate comprising a gap, the method comprising:
depositing a liner in a first portion of the gap, the first portion extending from a top of the gap to a selected depth within the gap, and not depositing the liner in a second portion of the gap that extends from the selected depth to a bottom of the gap; and
performing a plurality of atomic layer deposition (ALD) cycles to deposit a silicon-containing oxide in the second portion of the gap, an ALD cycle of the plurality of ALD cycles comprising exposing the substrate to an inhibitor under conditions configured to deposit the inhibitor into the gap such that a concentration of the inhibitor deposited at a first depth is greater than a concentration of the inhibitor deposited at a second depth within the gap, the second depth being within the second portion of the gap and the second depth being farther from the top of the gap than the first depth.

11. The method of claim 10, further comprising removing the liner from the first portion of the gap.

12. The method of claim 10, wherein depositing the liner comprises depositing a silicon nitride liner.

13. The method of claim 10, wherein depositing the liner comprises using a plasma to deposit the liner

14. The method of claim 10, wherein the ALD cycle of the plurality of ALD cycles further comprises exposing the substrate to a silicon-containing precursor to absorb the silicon-containing precursor onto the substrate and then oxidizing the silicon-containing precursor.

15. The method of claim 10, further comprising performing an ALD cycle of the plurality of ALD cycles that omits exposing the substrate to the inhibitor.

16. The method of claim 10, wherein the inhibitor comprises one or more of molecular fluorine, hydrogen fluoride, boron trifluoride, phosphorus trifluoride, nitrogen trifluoride, a chlorofluorocarbon, a fluorocarbon, a hydrofluorocarbon, a chalcogen fluoride, a chalcogen chloride, or an interhalogen.

17. A structure formed on a substrate in an integrated circuit manufacturing process, the structure comprising:
a gap;
a silicon nitride film disposed within a first portion of the gap, the first portion extending from an opening of the gap to a selected depth within the gap; and
an oxide film within the gap, the oxide film at least partially filling a second portion of the gap, the second portion of the gap extending from the selected depth to a bottom of the gap.

18. The structure of claim 17, wherein the silicon nitride film comprises a halogenated surface.

19. The structure of claim 17, wherein the structure is part of a three-dimensional memory structure.

20. The structure of claim 17, wherein the silicon nitride film comprises a thickness within a range of 3-100 Å.
